(19) United States
(12) Patent Application Publication
(10) Pub. No.: US 2017/0207078 A1
(43) Pub. Date: Jul. 20, 2017

(54) ATOMIC LAYER DEPOSITION APPARATUS AND SEMICONDUCTOR PROCESS

(71) Applicant: Taiwan Semiconductor Manufacturing Co., Ltd., Hsinchu (TW)

(72) Inventors: You-Hua Chou, Hsinchu City (TW); Kuo-Sheng Chuang, Hsinchu City (TW)

(21) Appl. No.: 14/996,225

(22) Filed: Jan. 15, 2016

(51) Int. Cl. H01L 21/02; C23C 16/455

(52) U.S. Cl. CPC H01L 21/0228; H01L 21/02274; C23C 16/45563

(57) ABSTRACT

An atomic layer deposition apparatus comprises a processing chamber, at least one partition and an injector. The at least one partition is disposed in the processing chamber for dividing the processing chamber into a plurality of sections. The injector includes a plurality of nozzles disposed in the processing chamber and configured to respectively provide a reacting gaseous flow to each of the plurality of sections. A semiconductor process is also provided.

### BACKGROUND

An atomic layer deposition (ALD) process is a well-known deposition technique in the semiconductor industry. The ALD process employs a precursor material which can react with or chemisorb on a surface in process to build up successively deposited layers, each of which layers being characterized with thickness about only one atomic layer. Subject to properly selected process conditions, the chemisorption reaction has a self-limiting characteristic, meaning that the amount of precursor material deposited in every reaction cycle is constant and the precursor material is restricted to growing on the surface, and therefore the film thickness can be easily and precisely controlled by the number of the applied growth cycles.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an ALD apparatus according to an embodiment of the present disclosure.

FIG. 2 illustrates an ALD apparatus according to another embodiment of the present disclosure.

FIG. 3 illustrates an ALD apparatus according to another embodiment of the present disclosure.

FIG. 4 illustrates an ALD apparatus according to another embodiment of the present disclosure.

FIG. 5 illustrates an ALD apparatus according to another embodiment of the present disclosure.

FIG. 6 illustrates an ALD apparatus according to another embodiment of the present disclosure.

FIG. 7 illustrates an ALD apparatus according to another embodiment of the present disclosure.

FIG. 8 is a flow chart illustrating a semiconductor process according to an embodiment of the present disclosure.

FIG. 9 is a flow chart illustrating a semiconductor process according to another embodiment of the present disclosure.

FIG. 10 is a flow chart illustrating a semiconductor process according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

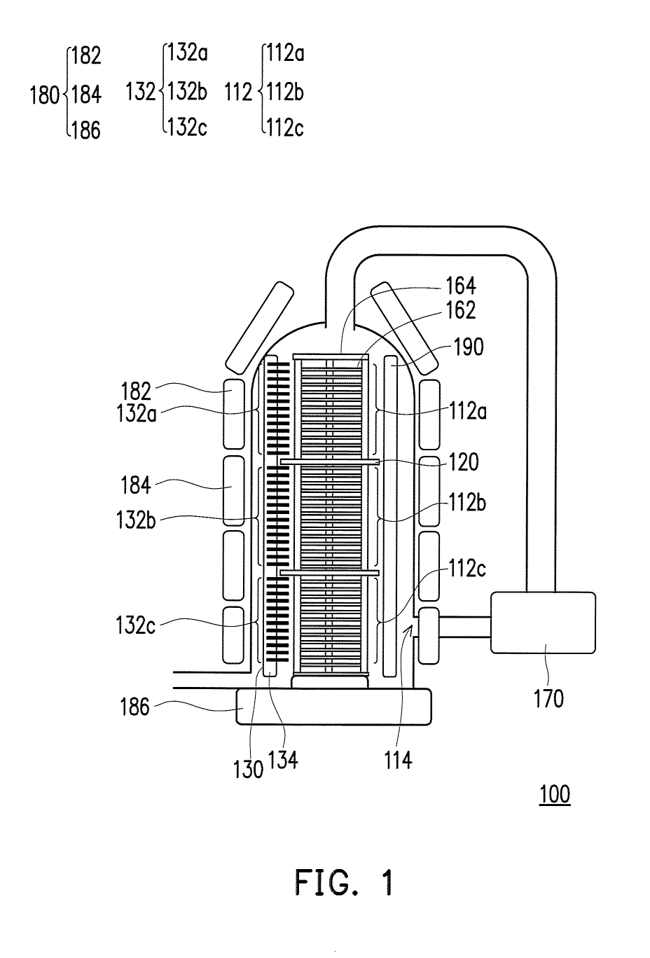

FIG. 1 illustrates an ALD apparatus according to an embodiment of the present disclosure. The ALD apparatus 100 includes a furnace 110 having a processing chamber 112, and partitions 120 are disposed in the processing chamber 112 for dividing the processing chamber 112 into a plurality of sections, such as sections 112a, 112b and 112c. In addition, an injector 130 comprising a plurality of nozzles 132 is disposed in the processing chamber 112, wherein the nozzles 132 are configured to respectively provide a reacting gaseous flow to each of the sections 112a, 112b and 112c. More specifically, the nozzles 132 can be divided into three groups of nozzles 132a, 132b and 132c, which may be individually controlled such as MFC program to respectively provide reacting gaseous flows to the sections 112a, 112b and 112c.

In some embodiments, the ALD apparatus 100 may further include a plasma tube 190 in the processing chamber 112 for enhancing the ALD process, to ensure film uniformity and minimize both precursor consumption and cycle time.

In some embodiments, the ALD apparatus 100 can be applied to form structures on a batch of substrates 162 (e.g. silicon wafers) carried by a substrate carrier 164. For example, multiple ALD reaction cycles may be performed, wherein each of the ALD reaction cycles involves consequently performing steps of introducing a reacting gaseous flow including gaseous precursor by the injector 130 to a surface of each of the substrates 162, pulsing an inert gas to purge or evacuate the excess gaseous precursor after the surface of each of the substrates 162 is saturated with an atomic layer of the gaseous precursor. A single ALD reaction cycle is continuously repeated until a target thickness for the deposited atomic layer on the surface in process is achieved.

In some embodiments, the processing chamber 112 is in controllable communication with a vacuum pump 170, which is capable of evacuating the excess gaseous precursor or other gases by extraction through a pumping port 114 of the furnace 110.

In some embodiments, the ALD apparatus 100 is widely applicable for growing a thin film, such as a high-k dielectric layer, a diffusion barrier layer, a seed layer, a sidewall, a sidewall oxide, a sidewall spacer for a gate, a metal interconnect and a metal liner etc., in a semiconductor electronic element. For example, in a formation of a high-k dielectric layer, for forming films such as an Al2O3 film, a HfO2 film and a ZrO2 film acting as a high-k dielectric layer, corresponding candidate precursor material pair can be chosen as Al(CH3)3 plus either H2O or O3, either HfCl4 or TEMAH plus H2O and ZrCl4 plus H2O. H2O may be a popular candidate for acting as a precursor material since H2O vapor is adsorbed on most materials or surfaces including a surface of a silicon wafer.

In general, a full batch ALD process is difficult to be controlled due to “pattern effect” and “loading effect”. More specifically, one batch of ALD process can only form one scale of thickness for an ALD layer on a wafer in the furnace. However, pattern density (e.g. size, thickness, etc.) of a part of the wafers in a full batch may be different from others (the so-called “pattern effect”), or different wafers may require different thermal capacity for ALD process (the so-called “Loading effect”). Thus, there arises a difficulty to reach full batch control, and lead to a limitation on the efficiency of ALD process for substrate capacity utilization, while the quantity of the same thickness of wafer in process (WIP) would be lower than the full batch load.

As to the above, the ALD apparatus 100 of the present embodiment is provided with the processing chamber 112 being divided into plural sections such as 112a, 112b and 112c. By which, the ALD process in the different sections 112a, 112b and 112 of the processing chamber 112 can be individually controlled to improve WIP performance and achieve high tool efficiency in the batch load process.

More specifically, the independent groups of nozzles 132a, 132b and 132c of the injector 130 may be provided with different geometric parameters from each other. Herein, the geometric parameter is for example an opening size of the nozzle 132a, 132b or 132c. In some embodiments, the opening size of the nozzle 132a, 132b or 132c may be varied from 2 mm to 3 mm. Furthermore, the reacting gaseous flows from the nozzles 132a, 132b and 132c can be provided synchronously through an injector tube 134 in a synchronized ALD process, while different processing controls among different sections 112a, 112b and 112c can still be achieved through the nozzles 132a, 132b and 132c having different opening sizes.

In addition, referring to FIG. 1, the ALD apparatus 100 may further includes a heating device 180 being outside the processing chamber 112. For example, the heating device 180 may include a top heating device 182 disposed above a top of the furnace 110, a bottom heating device 184 disposed below a bottom of the furnace 110, and a side heating device 186 beside a side wall of the furnace 110, to achieve fully surrounding temperature control for the different sections 112a, 112b and 112c of the processing chamber 112.

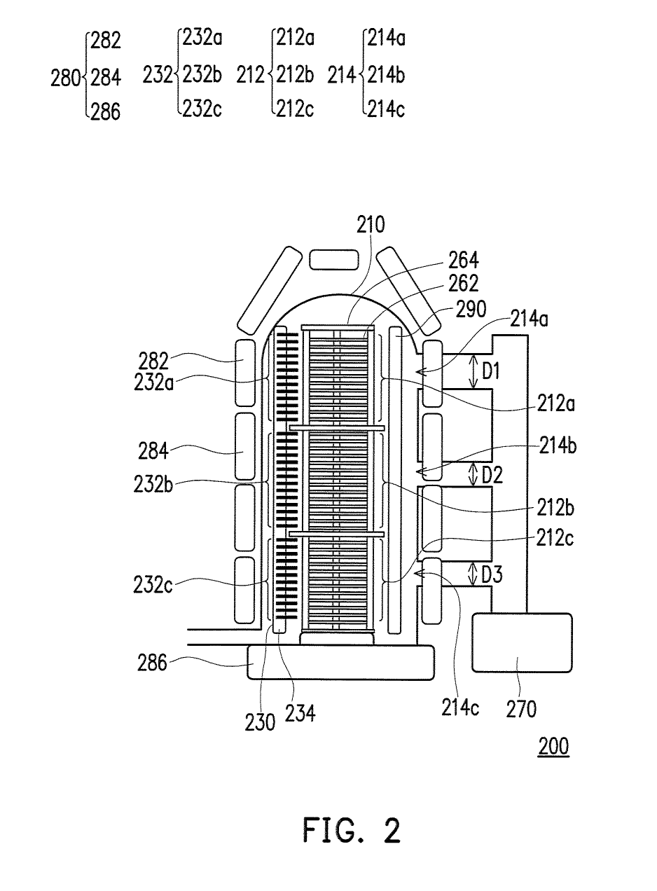

FIG. 2 illustrates an ALD apparatus according to another embodiment of the present disclosure. The ALD apparatus 200 includes a furnace 210 having a processing chamber 212, and partitions 220 are disposed in the processing chamber 212 for dividing the processing chamber 212 into a plurality of sections, such as sections 212a, 212b and 212c. In addition, an injector 230 comprising a plurality of nozzles 232 is disposed in the processing chamber 212, wherein the nozzles 232 are configured to respectively provide a reacting gaseous flow to each of the sections 212a, 212b and 212c. More specifically, the nozzles 232 can be divided into three groups of nozzles 232a, 232b and 232c, which may be individually controlled such as MFC program to respectively provide reacting gaseous flows to the sections 212a, 212b and 212c.

In some embodiments, the ALD apparatus 200 may further include a plasma tube 290 in the processing chamber 212 for enhancing the ALD process, to ensure film uniformity and minimize both precursor consumption and cycle time.

In some embodiments, the ALD apparatus 200 can be applied to form structures on a batch of substrates 262 (e.g. silicon wafers) carried by a substrate carrier 264. For example, multiple ALD reaction cycles may be performed, wherein each of the ALD reaction cycles involves consequently performing steps of introducing a reacting gaseous flow including gaseous precursor by the injector 230 to a surface of each of the substrates 262, pulsing an inert gas to purge or evacuate the excess gaseous precursor after the surface of each of the substrates 262 is saturated with an atomic layer of the gaseous precursor. A single ALD reaction cycle is continuously repeated until a target thickness for the deposited atomic layer on the surface in process is achieved.

Similar to the above embodiment as shown in FIG. 1, the ALD apparatus 200 of the present embodiment is provided with the processing chamber 212 being divided into plural sections such as 212a, 212b and 212c with different geometric parameters from each other. Herein, the geometric parameter is for example an opening size of the nozzle 232a, 232b or 232c. In some embodiments, the opening size of the nozzle 232a, 232b or 232c may be varied from 2 mm to 3 mm. And, the reacting gaseous flows from the nozzles 232a, 232b and 232c can be provided synchronously through an injector tube 234.

Furthermore, in the present embodiment, the processing chamber 212 is in controllable communication with a vacuum pump 270 through a plurality of pumping ports 214 on the furnace 210, to evacuate the reacting gaseous flows from the processing chamber 212. More specifically, the pumping ports 214 may include pumping ports 214a, 214b and 214c, which are corresponding to the sections 212a, 212b and 212c, for respectively evacuating the reacting gaseous flows from the sections 212a, 212b and 212c. Evacuation through the pumping ports 214a, 214b and 214c can be performed synchronously by the vacuum pump 270.

According to the above, different or individual processing controls among different sections 212a, 212b and 212c can be achieved through the individual nozzles 232a, 232b and 232c and the different pumping ports 214a, 214b and 214c. In some embodiments, the pumping ports 214 are provided with different geometric parameters such as opening sizes. For example, the pumping port 214a is provided with an opening size D1, the pumping port 214b is provided with an opening size D2, and the pumping port 214c is provided with an opening size D3, while D1 is greater than D2, and D2 is greater than D3, to provide different pumping efficiencies. By which, a synchronized ALD process in the different sections 212a, 212b and 212 of the processing chamber 212 can be individually controlled in the present embodiment to improve WIP performance and achieve high tool efficiency in the batch load process.

In addition, referring to FIG. 2, the ALD apparatus 200 may further includes a heating device 280 being outside the processing chamber 212. For example, the heating device 280 may include a top heating device 282 disposed above a top of the furnace 210, a bottom heating device 284 disposed below a bottom of the furnace 210, and a side heating device 286 beside a side wall of the furnace 210, to achieve fully surrounding temperature control for the different sections 212a, 212b and 212c of the processing chamber 212.

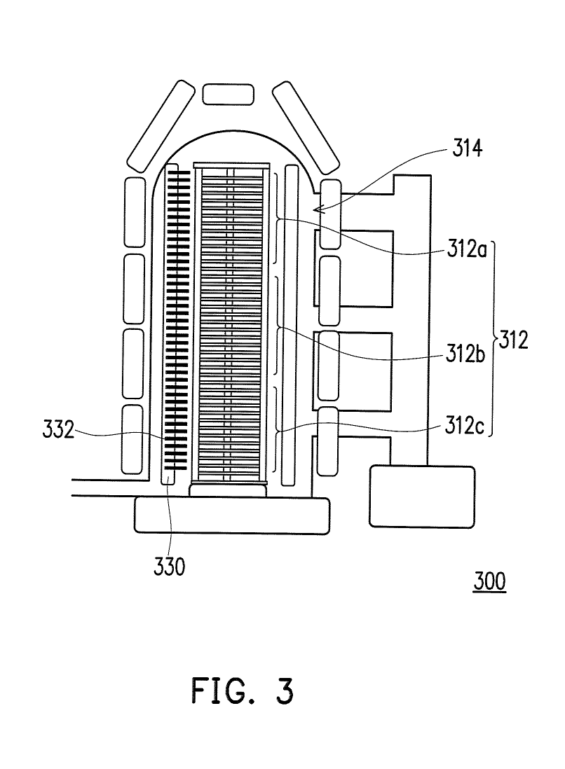

FIG. 3 illustrates an ALD apparatus according to another embodiment of the present disclosure. The ALD apparatus 300 of the present embodiment is similar to the ALD apparatus 200 of the previous embodiment as shown in FIG. 2, except that partitions 220 in FIG. 2 are optionally removed. Although there are no partitions provided in the processing chamber 312 of the present embodiment, different or individual processing controls among different sections 312a, 312b and 312c may still achieve through individual controlled nozzles 332 of the injector 330 or pumping ports 314 in different geometric parameters, as illustrated in the previous embodiments.

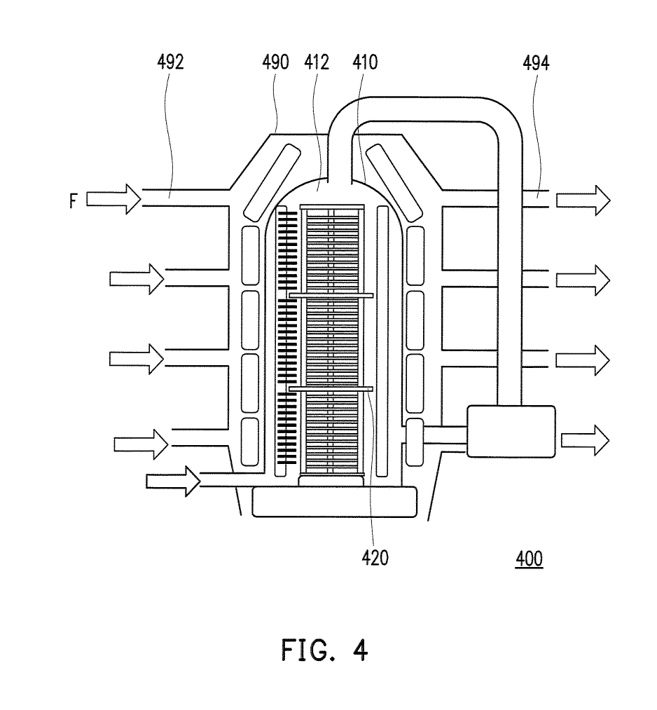

FIG. 4 illustrates an ALD apparatus according to another embodiment of the present disclosure. The ALD apparatus 400 of the present embodiment is similar to the ALD apparatus 100 of the previous embodiment as shown in FIG. 1, except that the ALD apparatus 400 of the present embodiment further includes a cooling chamber 490 accommodating the processing chamber 412. The cooling chamber 490 includes one or more inlet ports 492 disposed at a side of the processing chamber 412 and one or more outlet ports 494 disposed at an opposite side of the processing chamber 412. In other words, the one or more inlet ports 492 and the one or more outlet ports 494 may be disposed on symmetric positions outside the processing chamber 412. By which, a cooling fluid F such as gas or liquid can be provided through the one or more inlet ports 492, passing the processing chamber 412 from the side to the other side in substantially horizontal direction, and then outputted from the one or more outlet ports 494.

In some embodiments, temperature of the cooling fluid F may be controlled to vary in gradient according to different ALD reaction cycles, so as to control and speed up cooling efficiency and lower crack risk of devices, such as the furnace 410, in the cooling chamber 490.

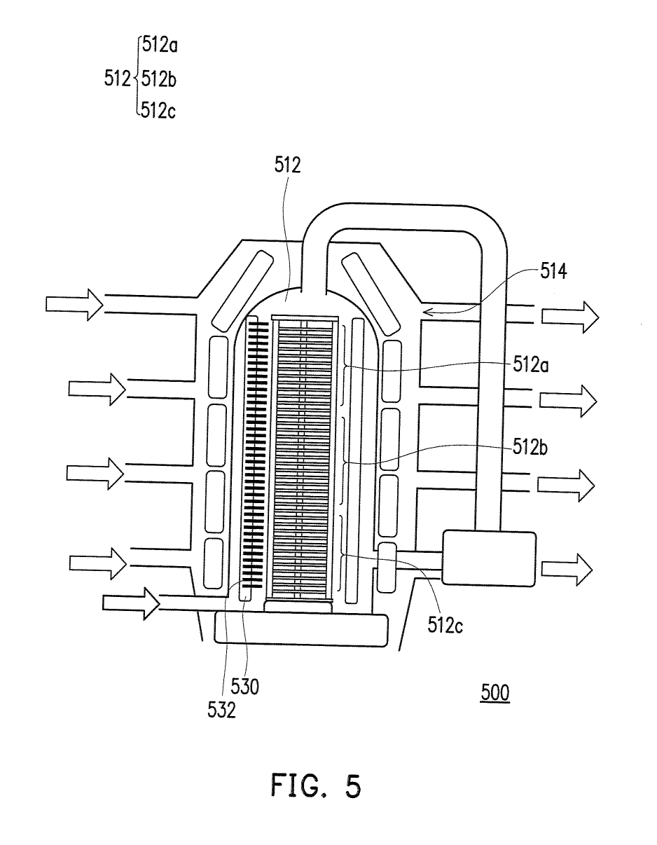

FIG. 5 illustrates an ALD apparatus according to another embodiment of the present disclosure. The ALD apparatus 500 of the present embodiment is similar to the ALD apparatus 400 of the previous embodiment as shown in FIG. 4, except that partitions 420 in FIG. 4 are optionally removed. Although there are no partitions provided in the processing chamber 512 of the present embodiment, different or individual processing controls among different sections 512a, 512b and 512c can still achieve through individual controlled nozzles 532 of the injector 530 or pumping ports 514 in different geometric parameters, as illustrated in the previous embodiments.

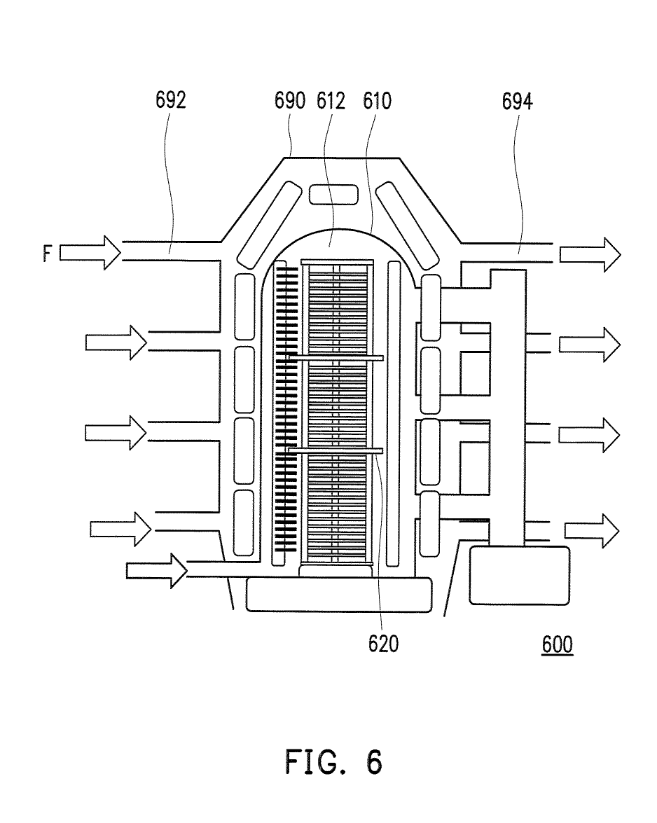

FIG. 6 illustrates an ALD apparatus according to another embodiment of the present disclosure. The ALD apparatus 600 of the present embodiment is similar to the ALD apparatus 200 of the previous embodiment as shown in FIG. 2, except that a cooling chamber 690 accommodating the processing chamber 612 is provided in the present embodiment. The cooling chamber 690 includes one or more inlet ports 692 disposed at a side of the processing chamber 612 and one or more outlet ports 694 disposed at an opposite side of the processing chamber 612. In other words, the one or more inlet ports 692 and the one or more outlet ports 694 may be disposed on symmetric positions outside the processing chamber 612. By which, a cooling fluid F such as gas or liquid can be provided through the one or more inlet ports 692, passing the processing chamber 612 from the side to the other side in substantially horizontal direction, and then outputted from the one or more outlet ports 694.

In some embodiments, temperature of the cooling fluid F may be controlled to vary in gradient according to different ALD reaction cycles, so as to control and speed up cooling efficiency and lower crack risk of devices, such as the furnace 610, in the cooling chamber 690.

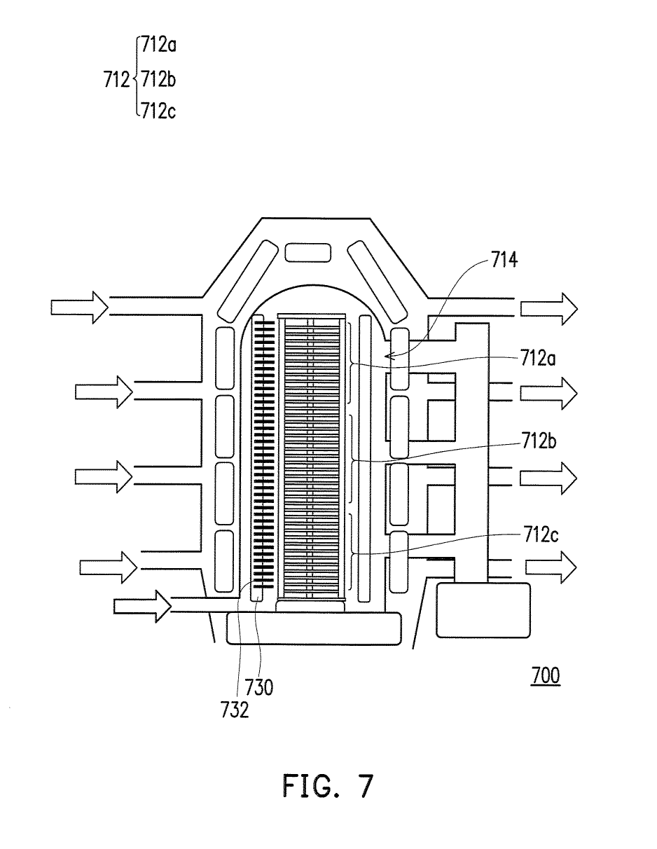

FIG. 7 illustrates an ALD apparatus according to another embodiment of the present disclosure. The ALD apparatus 700 of the present embodiment is similar to the ALD apparatus 600 of the previous embodiment as shown in FIG. 6, except that partitions 620 in FIG. 6 are optionally removed. Although there are no partitions provided in the processing chamber 712 of the present embodiment, different or individual processing controls among different sections 712a, 712b and 712c can still achieve through individual controlled nozzles 732 of the injector 730 or pumping ports 714 in different geometric parameters, as illustrated in the previous embodiments.

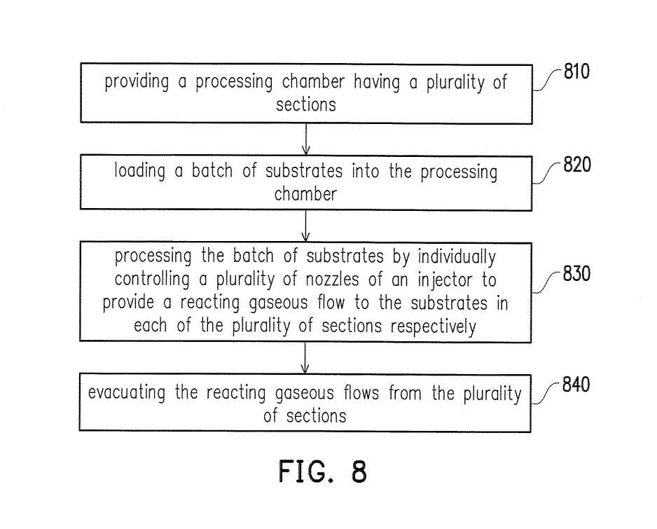

FIG. 8 is a flow chart illustrating a semiconductor process such as an ALD process according to an embodiment of the present disclosure.

At first, a processing chamber having a plurality of sections is provided (Step 810). And, a batch of substrates 162 is loaded into the processing chamber 112 (Step 820). For example, as shown in FIG. 1, the processing chamber 112 may be divided into a plurality of sections, such as sections 112a, 112b and 112c, by partitions 120.

Then, the batch of substrates 162 is processed, wherein a plurality of nozzles of an injector can be individually controlled to provide a reacting gaseous flow to each of the plurality of sections respectively (Step 830). For example, as shown in FIG. 1, the independent groups of nozzles 132a, 132b and 132c of the injector 130 may be provided with different geometric parameters from each other. Herein, the geometric parameter is for example an opening size of the nozzle 132a, 132b or 132c, such that individual processing controls among different sections 112a, 112b and 112c can be achieved through the nozzles 132a, 132b and 132c having different opening sizes.

Next, the reacting gaseous flows can be evacuated from the plurality of sections (Step 840). For example, as shown in FIG. 1, the processing chamber 112 is in controllable communication with a vacuum pump 170, which is capable of evacuating the excess gaseous precursor or other gases by extraction through a pumping port 114 of the furnace 110.

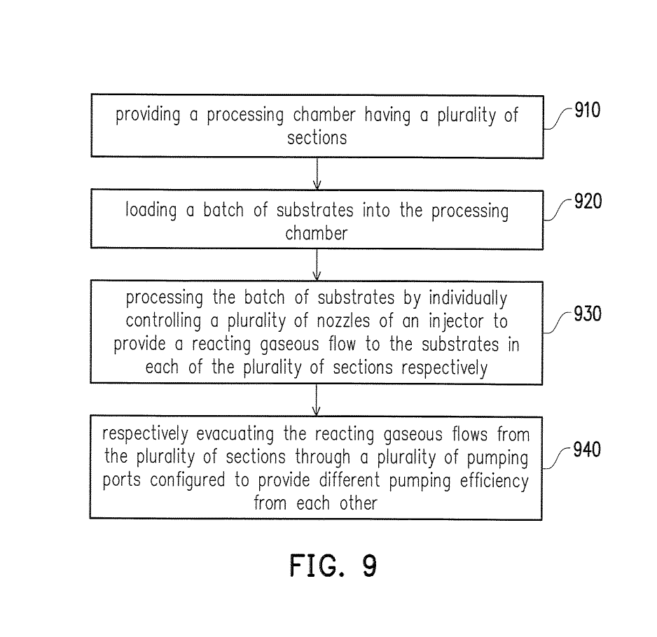

FIG. 9 is a flow chart illustrating a semiconductor process such as an ALD process according to another embodiment of the present disclosure.

At first, a processing chamber having a plurality of sections is provided (Step 910). And, a batch of substrates 262 is loaded into the processing chamber 212 (Step 920). For example, as shown in FIG. 2, the processing chamber 212 may be divided into a plurality of sections, such as sections 212a, 212b and 212c, by partitions 220.

Then, the batch of substrates 262 is processed, wherein a plurality of nozzles of an injector can be individually controlled to provide a reacting gaseous flow to each of the plurality of sections respectively (Step 930). For example, as shown in FIG. 2, the independent groups of nozzles 232a, 232b and 232c of the injector 230 may be provided with different geometric parameters from each other. Herein, the geometric parameter is for example an opening size of the nozzle 232a, 232b or 232c, such that individual processing controls among different sections 212a, 212b and 212c can be achieved through the nozzles 232a, 232b and 232c having different opening sizes.

Next, the reacting gaseous flows can be evacuated from the plurality of sections (Step 940). For example, as shown in FIG. 2, the pumping ports 214 are provided with different geometric parameters such as opening sizes. For example, the pumping port 214a is provided with an opening size D1, the pumping port 214b is provided with an opening size D2, and the pumping port 214c is provided with an opening size D3, while D1 is greater than D2, and D2 is greater than D3, to provide different pumping efficiencies. By which, a synchronized ALD process in the different sections 212a, 212b and 212 of the processing chamber 212 can be individually controlled in the present embodiment to improve WIP performance and achieve high tool efficiency in the batch load process.

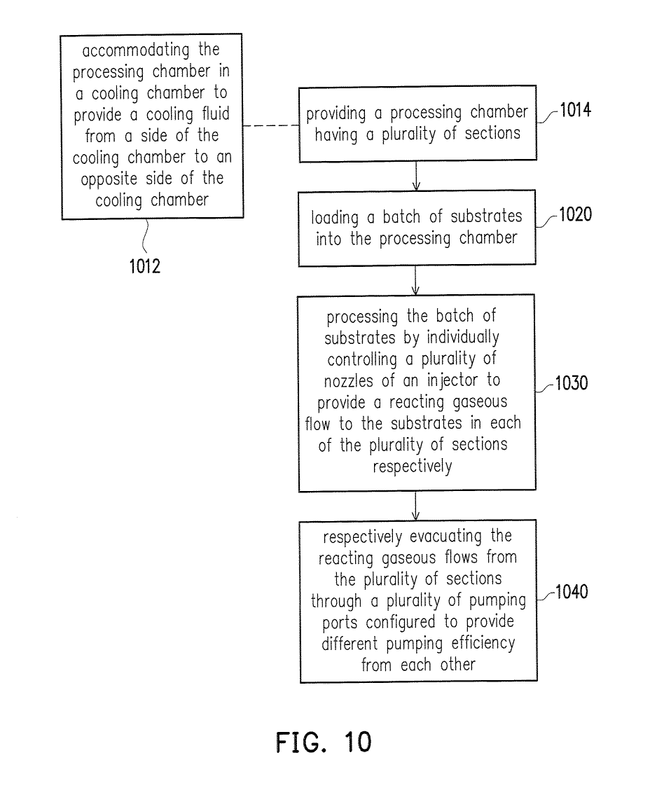

FIG. 10 is a flow chart illustrating a semiconductor process such as an ALD process according to another embodiment of the present disclosure. The ALD process includes: providing a processing chamber having a plurality of sections (Step 1014), loading a batch of substrates into the processing chamber (Step 1020). individually controlling a plurality of nozzles of an injector to provide a reacting gaseous flow to each of the plurality of sections respectively (Step 1030), and respectively evacuating the reacting gaseous flows from the plurality of sections through a plurality of pumping ports configured to provide different pumping efficiency from each other (Step 1040), which are similar to the steps 910-940 of the previous embodiment of FIG. 9. Thus, detailed descriptions of Steps 1014, 1020, 1030 and 1040 can be referred to the previous embodiment, and are not repeated hereinafter.

Furthermore, the ALD process of the present embodiment further includes accommodating the processing chamber in a cooling chamber to provide a cooling fluid from a side of the cooling chamber to an opposite side of the cooling chamber (Step 1012). For example, as shown in FIG. 6, a cooling chamber 690 accommodating the processing chamber 612 is provided. The cooling chamber 690 includes one or more inlet ports 692 disposed at a side of the processing chamber 612 and one or more outlet ports 694 disposed at an opposite side of the processing chamber 612. By which, a cooling fluid F such as gas or liquid can be provided through the one or more inlet ports 692, passing the processing chamber 612 from the side to the other side in substantially horizontal direction, and then outputted from the one or more outlet ports 694. In some embodiments, temperature of the cooling fluid F may be controlled to vary in gradient according to different ALD reaction cycles, so as to control and speed up cooling efficiency and lower crack risk of devices, such as the furnace 610, in the cooling chamber 690.

According to some embodiments, an atomic layer deposition apparatus comprises a processing chamber, at least one partition and an injector. The at least one partition is disposed in the processing chamber for dividing the processing chamber into a plurality of sections. The injector includes a plurality of nozzles disposed in the processing chamber and configured to respectively provide a reacting gaseous flow to each of the plurality of sections.

According to some embodiments, an atomic layer deposition apparatus includes a processing chamber, an injector, a heating device and a cooling chamber. The processing chamber has a plurality of sections. The injector includes a plurality of nozzles disposed in the processing chamber and configured to respectively provide a reacting gaseous flow to each of the plurality of sections. The processing chamber includes a plurality of pumping ports configured to evacuate the reacting gaseous flows from the sections of the processing chamber respectively. The heating device is located outside the processing chamber. The cooling chamber accommodates the processing chamber and the heating device.

According to some embodiments, a semiconductor process comprises: providing a processing chamber having a plurality of sections; loading a batch of substrates into the processing chamber; processing the batch of substrates by individually controlling a plurality of nozzles of an injector to provide a reacting gaseous flow to each of the plurality of sections respectively; and, evacuating the reacting gaseous flows from the plurality of sections.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An atomic layer deposition apparatus, comprising:
a processing chamber;
at least one partition disposed in the processing chamber for dividing the processing chamber into a plurality of sections; and
an injector comprising a plurality of nozzles disposed in the processing chamber and configured to respectively provide a reacting gaseous flow to each of the plurality of sections.

2. The atomic layer deposition apparatus according to claim 1, wherein the plurality of nozzles comprises:
a first nozzle having a first geometric parameter and configured to provide a first reacting gaseous flow to a first section of the processing chamber; and
a second nozzle having a second geometric parameter different from the first geometric parameter and configured to provide a second reacting gaseous flow to a second section of the processing chamber.

3. The atomic layer deposition apparatus according to claim 2, wherein the first geometric parameter comprises an opening size of the first nozzle, and the second geometric parameter comprises an opening size of the second nozzle.

4. The atomic layer deposition apparatus according to claim 1, wherein the processing chamber comprises a plurality of pumping ports configured to evacuate the reacting gaseous flows from the processing chamber.

5. The atomic layer deposition apparatus according to claim 4, wherein the plurality of pumping ports comprises:
a first pumping port having a third geometric parameter and configured to evacuate a first reacting gaseous flows from a first section of the processing chamber; and
a second pumping port having a fourth geometric parameter different from the third geometric parameter and configured to evacuate a second reacting gaseous flows from a second section of the processing chamber.

6. The atomic layer deposition apparatus according to claim 5, wherein the third geometric parameter comprises an opening size of the first pumping port, and the fourth geometric parameter comprises an opening size of the second pumping port.

7. The atomic layer deposition apparatus according to claim 1, further comprising a heating device being outside the processing chamber.

8. The atomic layer deposition apparatus according to claim 7, wherein the heating device comprises:
a top heating device disposed above a top of the processing chamber;
a bottom heating device disposed below a bottom of the processing chamber; and
a side heating device beside a side wall of the processing chamber.

9. The atomic layer deposition apparatus according to claim 1, further comprising a cooling chamber accommodating the processing chamber, wherein the cooling chamber comprises:
an inlet port disposed at a side of the processing chamber; and
an outlet port disposed at an opposite side of the processing chamber.

10. An atomic layer deposition apparatus, comprising:
a processing chamber having a plurality of sections;
an injector comprising a plurality of nozzles disposed in the processing chamber and configured to respectively provide a reacting gaseous flow to each of the plurality of sections, the processing chamber comprising a plurality of pumping ports configured to evacuate the reacting gaseous flows from the sections of the processing chamber respectively;
a heating device being outside the processing chamber; and
a cooling chamber accommodating the processing chamber and the heating device.

11. The atomic layer deposition apparatus according to claim 10, further comprising at least one partition disposed in the processing chamber for dividing the processing chamber into the plurality of sections.

12. The atomic layer deposition apparatus according to claim 10, wherein the nozzles have different geometric parameters from each other.

13. The atomic layer deposition apparatus according to claim 12, wherein the geometric parameter comprises an opening size of one of the nozzles.

14. The atomic layer deposition apparatus according to claim 10, wherein the pumping ports have different geometric parameters from each other.

15. The atomic layer deposition apparatus according to claim 14, wherein the geometric parameter comprises an opening size of one of the pumping ports.

16. The atomic layer deposition apparatus according to claim 10, wherein the cooling chamber comprises:
an inlet port disposed at a side of the processing chamber; and
an outlet port disposed at an opposite side of the processing chamber.

17. A semiconductor process, comprising:
providing a processing chamber having a plurality of sections;
loading a batch of substrates into the processing chamber;
processing the batch of substrates by individually controlling a plurality of nozzles of an injector to provide a reacting gaseous flow to the substrates in each of the plurality of sections respectively; and
evacuating the reacting gaseous flows from the plurality of sections.

18. The semiconductor process according to claim 17, wherein respectively evacuating the reacting gaseous flows from the plurality of sections through a plurality of pumping ports configured to provide different pumping efficiency from each other.

19. The semiconductor process according to claim 17, further comprising accommodating the processing chamber in a cooling chamber to provide a cooling fluid from a side of the cooling chamber to an opposite side of the cooling chamber.

20. The semiconductor process according to claim 19, wherein temperature of the cooling fluid is varied in gradient.
